(19) United States
(12) Patent Application Publication
(10) Pub. No.: US 2023/0398580 A1
(43) Pub. Date: Dec. 14, 2023

(54) SUBSTRATE CLEANING APPARATUS

(71) Applicant: KCTECH CO., LTD., Anseong-si (KR)

(72) Inventor: Ji Hoon SON, Osan-si (KR)

(73) Assignee: KCTECH CO., LTD., Anseong-si (KR)

(21) Appl. No.: 18/144,718

(22) Filed: May 8, 2023

(30) Foreign Application Priority Data
Jun. 8, 2022 (KR) 10-2022-0069810

(51) Int. Cl. B08B 1/00; B08B 1/02; A46B 13/00; A46B 13/02; A46B 15/00; B08B 13/00

(52) U.S. Cl. CPC B08B 1/002; B08B 1/02; A46B 13/001; A46B 13/02; A46B 15/0038; A46B 15/0004; B08B 13/00; A46B 2200/3073; G08B 21/187

(57) ABSTRACT

Provided is a substrate cleaning apparatus, comprising: a substrate support unit for rotating and holding a substrate; a brush unit for cleaning the substrate with a cleaning brush formed in the form of a roll and rotating in contact with a surface of the substrate; and a vibration sensor installed on the brush unit to detect vibrations generated by the contact of the cleaning brush with the substrate, thereby improving process efficiency by predicting cleaning results before cleaning is completed.

### CROSS-REFERENCE TO RELATED APPLICATIONS

This U. S. non-provisional patent application claims priority under 35 U. S. C. § 119 of Korean Patent Application No. 10-2022-0069810 filed on Jun. 8, 2022 the entire contents of which are hereby incorporated by reference.

### BACKGROUND OF THE INVENTION

The present invention relates to a substrate cleaning apparatus, more particularly to a substrate cleaning apparatus which, in cleaning a substrate with a rotating cleaning brush, detects a cleaning error of the substrate in advance and resets an attitude of the substrate when a cleaning error is likely to occur thereby increasing a cleaning efficiency of the substrate.

Semiconductor devices are manufactured on substrates such as wafers through many processes such as deposition processes, polishing processes, and etching processes. After performing the above processes, a cleaning process is performed to remove unnecessary thin films, particles, and other foreign substances that remain on the substrate.

In particular, since many foreign substances remain on the surface of the substrate after the chemical mechanical polishing process, several cleaning processes are performed to remove the foreign substances. Herein, methods to improve the removal efficiency of the foreign substances remaining on the surface of the substrate are being sought.

Broadly speaking, the substrate cleaning apparatus 9 using the cleaning brush 50 performs a contact cleaning process of the substrate W by rotating r1 the substrate W in place and by rotating the roll-shaped cleaning brush 50 by the drive part M installed on the support 10, as shown in FIG. 1.

However, at the end of the substrate cleaning process using the same substrate cleaning apparatus 9, as shown in FIG. 2a, it is found that there are cases in which the foreign substance 66 is distributed in a large amount on the substrate W, and there are cases in which the foreign substance 66 is almost removed from the substrate W. In some cases, the foreign substance 66 has been completely removed.

Since deviations occur in the cleaning state of the substrate W being cleaned by the same substrate cleaning apparatus 9, it is necessary to uniformly control the cleaning state of the connection of the substrate using the cleaning brush. However, in the prior art, the cause of the deviation in the cleaning state of the substrate using the cleaning brush has not been known, and it was not possible to confirm that the cleaning state was defective until after the cleaning process was completed. Thus, the defective substrate had to be re-injected into the substrate cleaning apparatus 9 for re-cleaning, resulting in a deterioration of the cleaning process. In addition, there was a limitation that even if the defective substrate was re-cleaned, there was no guarantee that it would be cleaned properly.

In order to solve the above problems, a method of using a plane-shaped cleaning brush instead of a roll-shaped cleaning brush 50 has been explored, but the plane-shaped cleaning brush still has a problem of low cleaning efficiency of the substrate due to a small contact area and a long cleaning time.

### SUMMARY OF THE INVENTION

In order to solve the above problems, the present invention aims to make it possible to reliably and repeatedly realize the cleaning state of a substrate by using a roll-shaped cleaning brush while rotating the substrate.

In addition, the present invention aims to predict the cleaning status of the substrate before the cleaning process is completed using the cleaning brush and before the status of the substrate is checked visually or by camera, and to send a warning signal or stop the cleaning process in case that the cleaning process is about to fail, thereby preventing the progress of the wrong cleaning process and improving the overall cleaning process efficiency.

And, the present invention aims to improve the cleaning process efficiency by predicting the cleaning state of the substrate before the cleaning process is completed by using the cleaning brush and before the status of the substrate is checked visually or by camera, and to correct the wrong attitude of the substrate during the cleaning process that is expected to be defective, and to lead the substrate to a normal cleaning state.

In order to achieve the aforementioned aims of the present invention, the present invention provides a substrate cleaning apparatus, comprising: a substrate support unit for rotating and holding a substrate; a brush unit for cleaning the substrate with a cleaning brush formed in the form of a roll and rotating in contact with the surface of the substrate; and a vibration sensor installed on the brush unit to detect vibrations generated by the contact of the cleaning brush with the substrate.

The present invention also provides a substrate cleaning apparatus, from which it is possible to accurately predict the cleaning state of a substrate after cleaning process from the vibration of the cleaning brush without using the naked eye or camera before the cleaning process is completed.

In other words, the present invention allows the cleaning process by the cleaning brush to proceed when the cleaning is normal, and sends a warning signal or stops the cleaning process when the cleaning is predicted as defective, thereby preventing the progress of the defective cleaning process, reducing the process time spent on the defective cleaning time, and achieving the advantageous effect of increasing the overall cleaning process efficiency.

Furthermore, the present invention realizes advantageous effects of preventing the failed cleaning process in advance and increasing the cleaning efficiency, by correcting the posture of the substrate to be proper contact state between the substrate and the cleaning brush and thus changing the failed cleaning process into a normal cleaning process, when it detects the on-going cleaning process is expected to fail.

Accordingly, the present invention can reliably realize the normal cleaning of the substrate by using the roll-shaped cleaning brush, thereby achieving the advantageous effect of improving the cleaning efficiency of the substrate and enabling more substrates to complete the contact cleaning process per unit time.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view illustrating the configuration of a substrate cleaning apparatus with cleaning brushes.

FIG. 2A illustrates a face of a substrate after a defective cleaning process has been performed using the substrate cleaning apparatus of FIG. 1.

FIG. 2B illustrates a face of a substrate after a normal cleaning process has been performed using the substrate cleaning apparatus of FIG. 1.

FIG. 3 is a perspective view illustrating a configuration of a substrate cleaning apparatus according to one embodiment of the present invention.

FIG. 4 is a longitudinal sectional view of the support according to the cut line of FIG. 3.

FIG. 5 is a drawing depicting a configuration of the poor cleaning condition of the substrate of FIG. 3.

FIG. 6A and FIG. 6B are drawings depicting a configuration for correcting the poor cleaning condition of a substrate.

FIG. 7 is a flowchart illustrating the operation of the substrate cleaning apparatus of FIG. 3.

FIG. 8A to FIG. 8C are measurement graphs depicting frequency domain signals measured from the vibration sensor of FIG. 3.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, it will be described about an exemplary embodiment of the present invention in conjunction with the accompanying drawings.

As shown in the drawings, a substrate cleaning apparatus 100 according to one embodiment of the present invention comprises a substrate support unit 110 for supporting and rotating a substrate W in place, a brush unit 120 for cleaning the substrate W with cleaning brushes 121, 122 formed in a roll and rotating in contact with a surface of the substrate W, and a vibration sensor 130 installed on the brush unit 120 for detecting a vibration generated in a contact state of the substrate W with the cleaning brushes 121, 122, a memory 140 in which a vibration setting value for determining whether the operation of the substrate cleaning apparatus 100 is normal or not is stored, and a control unit 150 that receives a measured value of the vibration sensor 130 and compares it with the setting value stored in the memory 140 to detect in advance whether the operation of the substrate cleaning apparatus 100 is normal or not, and controls an action of the substrate support unit 110 and the brush unit 120 according to the detection result.

The substrate cleaning apparatus 100 according to the present invention is suitable for cleaning a disc-shaped substrate W, and can be utilized as a cleaning process to remove foreign matters by contact cleaning by the brush unit 120 in a state where there are a lot of foreign matters on the surface. For example, it can be utilized to clean the surface of the substrate W where a chemical mechanical polishing process has been finished and there are many foreign substances on the surface.

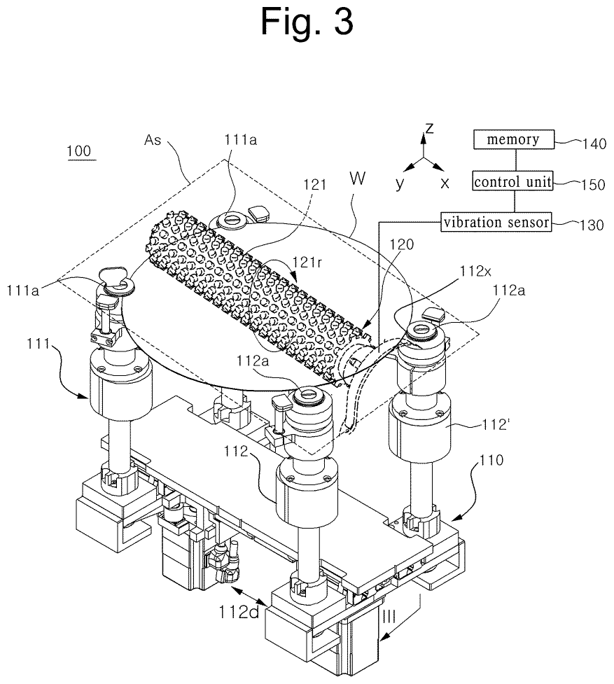

The substrate support unit 100, for rotating the substrate W while keeping it in a horizontal state, comprises a first support 111 rotatably installed on one side, and a second support 112, 112′ rotatably installed on the other side spaced apart from the first support 111, as shown in FIG. 3.

Here, both the first support 111 and the second support 112, 112′ may be formed to be rotationally driven by the drive part M, and one 112′ of the supports may be formed to driven to rotate by contact with the rotating substrate W without being rotationally driven by the drive part M. The number of revolutions of the support 112′ rotating driven by contact with the substrate W may be detected and used to detect the degree of cleaning of the substrate W.

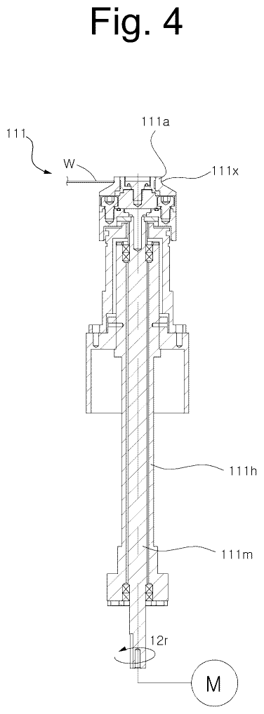

One of the rotationally driven supports 111, 112 may include, as shown in FIG. 4, a rotational shaft 111m capable of rotation 12r by the drive part M, a housing 111h enclosing the rotational shaft 111m, and a substrate holder 111a or 112a integrally coupled to the top end of the rotational shaft 111m. A ring-shaped receiving recess 111x is provided with the substrate holder 111a for receiving the substrate W.

Here, since the substrate holders 111a, 112a transmit a rotational driving force to the substrate W or receive a rotational driving force from the rotating substrate W while receiving an edge of the substrate W in the receiving recess 111x, 112x, it is preferable that the substrate holders 111a, 112a be formed of a material capable of elastic deformation or adhesive so that they remain in close contact with the substrate W at a position where they are in contact with the substrate. For example, the substrate holder 111a may be formed of a urethane-based or rubber-based material. Thus, the substrate holder 111a, 112a of each support 111, 112, 122′ can receive with elastic deformation the edge of the substrate W that is pushed by the cleaning brushes 121, 122, and reliably hold the edge of the substrate W and rotate the substrate W without slipping.

The brush unit 120 includes cleaning brushes 121, 122 in the form of rolls rotated by the drive unit, and clean the substrate W with the rotating cleaning brushes 121, 122. The brush unit 120 may include a single cleaning brush. However, according to the desirable embodiment of the present invention, as shown in the drawings, the upper cleaning brush 121 and the lower cleaning brush 122 are configured together to contact clean the upper and lower surfaces of the substrate W simultaneously. A rotation shaft is installed inside each of the cleaning brushes 121, 122, and the roll-shaped cleaning brushes 121, 122 are rotated 121r, 122r by rotationally driving the rotation shaft.

The cleaning brushes 121, 122 may be formed from a variety of materials and shapes. The cleaning brushes 121, 122 may be formed in the form of a roll with a plurality of protrusions formed on the outer circumferential surface to increase the cleaning efficiency of the substrate W, in which the substrate W is pressed during the cleaning process by a plurality of protrusions on the outer circumferential surface of the rotating roll-shaped brush. For example, the cleaning brushes 121, 122 may be made of a conventional material such as polyvinyl alcohol of a porous material for frictionally contacting the upper and lower surfaces of the substrate W.

Furthermore, according to one embodiment of the present invention, the cleaning brushes 121, 122 may be rotationally supported at both ends, or the cleaning brushes 121, 122 may be rotationally supported at one end like cantilever.

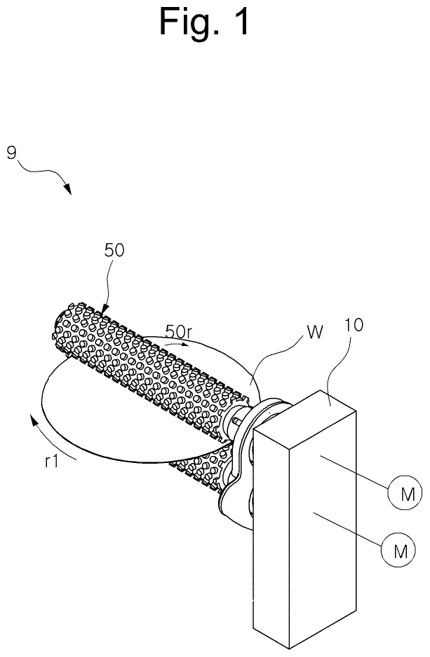

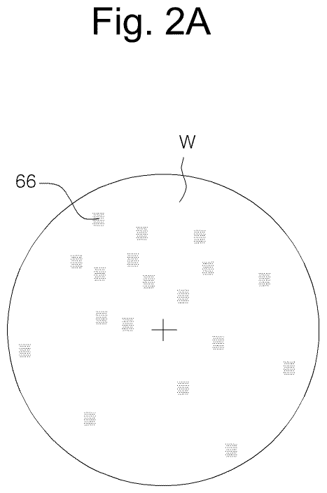

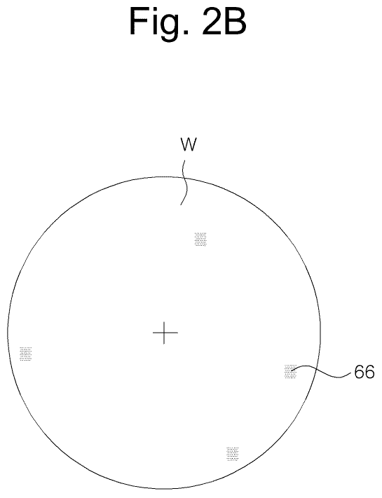

The vibration sensor 130 is installed to measure the vibration state of each of the cleaning brushes 121, 122. Accordingly, the vibration sensor 130 may be installed at least one of on the rotational shafts of one or more of the pair of cleaning brushes 121, 122, on the outer circumferential surface of the bearing rotationally supporting the rotational shaft, and on the support 10 in FIG. 1 on which the bearing is installed.

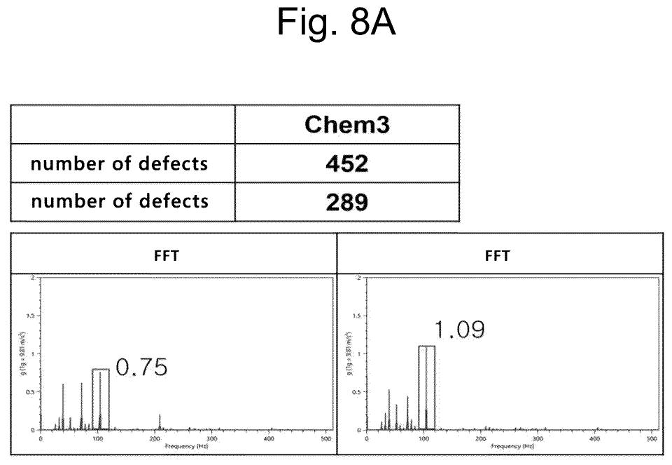

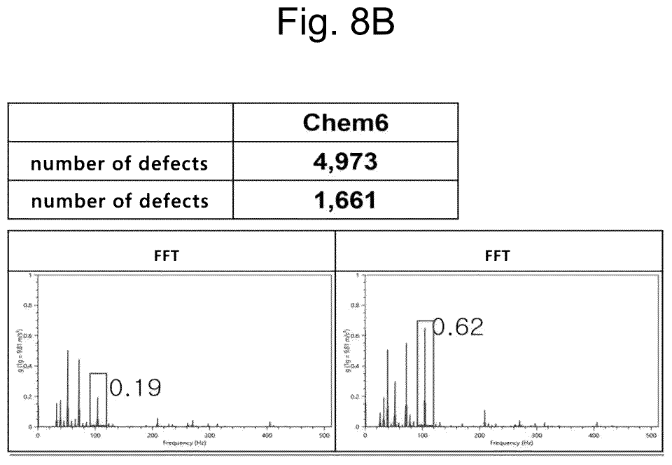

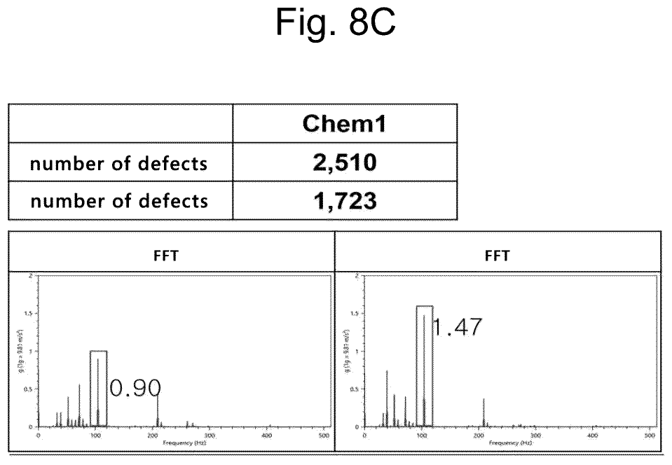

The vibration sensor 130 is used to measure the amplitude of the cleaning brushes 121, 122 during cleaning process. In particular only the amplitude at the rotational frequency of the cleaning brushes 121, 122 may be used as a measured value. For this purpose, the vibration signal of the vibration sensor 130 is converted into a signal in a frequency band by a Fast Fourier Transform (FFT) or the like, and the measured value is read from the control unit 150. For example, as shown in FIGS. 8a to 8c, the vibration signal measured by the vibration sensor 130 is converted by FFT to an amplitude value at a rotation frequency of the cleaning brushes 121, 122 of about 105 Hz, and the measured value is read by the control unit 150.

Here, the vibration sensor 130 may be a variety of sensors that measure the amplitude of the cleaning brushes 121, 122. According to other embodiments of the invention, a displacement sensor may be used to measure the amplitude of the cleaning brushes 121, 122, and according to a preferred embodiment of the invention, an acceleration sensor may be used.

Furthermore, it is essential to measure the amplitude in the vertical direction (z-axis), and preferably, the vibration sensor 130 may be a three-axis sensor which measures the amplitude in the horizontal direction (x-axis, y-axis) together with vertical direction (z-axis).

The present invention is based on a new discovery that the amplitude at the rotational frequency of the cleaning brushes 121, 122 can predict the cleaning result of the brush cleaning process of the substrate W. It has been realized that the cleaning state can be predicted in advance by the value of the amplitude at the rotational frequency of the cleaning brushes 121, 122.

That is, referring to FIG. 8A, in the case of contact cleaning of the substrate W using the cleaning brushes 121, 122 with the third chemical (chem3), when the z-axis amplitude at the rotation frequency of the cleaning brushes 121, 122 was 0.75, the number of defects remaining on the substrate W at the end of cleaning process was 452, whereas the number of defects remaining on the substrate W at the end of cleaning process was 289 when the z-axis amplitude at the rotation frequency of the cleaning brushes 121, 122 was 1.09, from which the number of defects remaining on the substrate W at the end of cleaning process tended to be smaller when the z-axis amplitude at the rotation frequency of the cleaning brushes 121, 122 is larger.

Also, referring to FIG. 8B, in the case of contact cleaning of the substrate W using the cleaning brushes 121, 122 with the sixth chemical (chem6), when the z-axis amplitude at the rotation frequency of the cleaning brushes 121, 122 is 0.19, the number of defects remaining on the substrate W at the end of cleaning process was 4973, whereas the number of defects remaining on the substrate W at the end of cleaning process was 1661 when the z-axis amplitude at the rotation frequency of the cleaning brushes 121, 122 was 0.62, from which the number of defects remaining on the substrate W at the end of cleaning process tended to be smaller when the z-axis amplitude at the rotation frequency of the cleaning brushes 121, 122 is larger.

And, referring to FIG. 8C, in the case of contact cleaning of the substrate W using the cleaning brushes 121, 122 with the first chemical (chem1), when the z-axis amplitude at the rotation frequency of the cleaning brushes 121, 122 was 0.90, the number of defects remaining on the substrate W at the end of cleaning process was 2510, whereas the number of defects remaining on the substrate W at the end of cleaning process was 1723 when the z-axis amplitude at the rotation frequency of the cleaning brushes 121, 122 was 1.47, from which the number of defects remaining on the substrate W at the end of cleaning process tended to be smaller when the z-axis amplitude at the rotation frequency of the cleaning brushes 121, 122 is larger.

From other experimental data, it was found that the larger the magnitude of the z-axis amplitude in the vertical directions, the fewer the number of defects remained on the substrate (W) at the end of the cleaning process, while the smaller the magnitude of the z-axis amplitude in the vertical directions, the more the number of defects remained on the substrate (W) at the end of the cleaning process, although the quantitative values of the z-axis amplitude in the vertical directions varied depending on the chemical used.

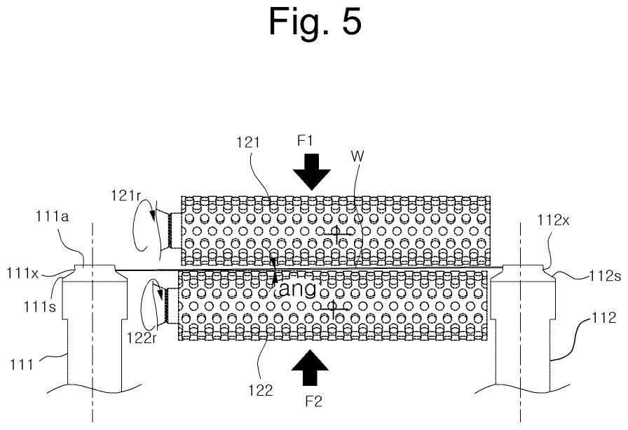

This means that the cleaning process should be carried out with the upper cleaning brush 121 pressing the substrate W downwardly (F1) and the lower cleaning brush 122 pressing the substrate W upwardly (F2), assuming that the substrate W is located exactly on the predetermined horizontal plane (As in FIG. 3), however, in practice, as the substrate W is positioned with some deviation in the receiving grooves 111x, 112x of the supports 111, 112, a tilt angle (ang in FIG. 5) is generated by which the substrate W is tilted with respect to an imaginary horizontal plane As perpendicular to the direction of gravity, and therefore, different cleaning processes result in different contact lengths with the substrate W of the upper and lower cleaning brushes 121, 122. In addition, in the case of the cantilevered upper and lower cleaning brushes 121, 122, the deflection displacement due to self-weight may also affect the contact state between the substrate W and the cleaning brushes 121, 122, although the effect is less significant compared with the tilt angle (ang) of the substrate.

In other words, if the contact area of the substrate W and the cleaning brushes 121, 122 is normal, the surface of the cleaning brushes 121, 122 will be in close contact with the surface of the substrate W along the entire length of the roll. On the other hand, if the contact area of the substrate W and the cleaning brushes 121, 122 is not normal, the surface of the cleaning brushes 121, 122 will be in close contact with the surface of the substrate W over a partial length of the roll. Accordingly, when the entire surface of the cleaning brushes 121, 122 is in contact with the substrate W, the amplitude of the vibration components in the vertical directions of the rotating cleaning brushes 121, 122 due to the rotation of the substrate W becomes larger. Further, when a partial surface of the cleaning brushes 121, 122 is in contact with the substrate W, the amplitude of the vibration components in the vertical directions of the rotating cleaning brushes 121, 122 due to the rotation of the substrate W becomes smaller.

Furthermore, when the entire length of the roll-shaped cleaning brushes 121, 122 is in contact with the substrate W, and the cleaning process can be realized in that the entire surface of the substrate W is in close contact with the rotating cleaning brushes and is swept by the rotating cleaning brushes to satisfy a predetermined standard through the cleaning process. On the other hand, if only a partial surface of the cleaning brushes 121, 122 is in contact with the substrate W, the cleaning brushes 121, 122 are repeatedly not in close contact with the partial surface of the substrate W. Therefore, the cleaning of the substrate W is performed poorly after the specified cleaning time has elapsed, and a poorly cleaned substrate that does not meet the standard is obtained.

In the present invention, the contact between the substrate W and the cleaning brushes 121, 122 cannot be checked visually during the cleaning process, but the contact between the substrate W and the cleaning brushes 121, 122 can be obtained by measuring the z-axis vibration of the cleaning brushes 121, 122 in the vertical directions. This is contrary to the common sense that the magnitude of the z-axis amplitude will be larger when there are more foreign objects on the substrate. In the present invention, a smaller magnitude of the z-axis amplitude of the cleaning brushes 121, 122 indicates that the cleaning brushes 121, 122 are in insufficient contact with the substrate W. From this, it can be concluded that, if the substrate W and the cleaning brushes 121, 122 are in a poor contact state, it is possible to predict in advance that a large amount of defects will remain even when this cleaning process is completely performed. Thus, the present invention has an advantageous effect of accurately predicting the cleaning result of the substrate during the cleaning process before inspecting the cleaning state of the substrate after the end of the cleaning process.

Here, the measured value measured by the vibration sensor 130 may be obtained by receiving a vibration signal for a time period of preferably about 1 second or more while the cleaning process is being performed, by FFT transforming a portion or sum of the received vibration signal from time-domain into frequency-domain, and selecting a z-axis amplitude signal at a rotational frequency of the cleaning brushes 121, 122 from the FFT transformed frequency-domain amplitude signal.

Here, the measurement of the vibration signal may be a value obtained by filtering out some abnormally low or high values in the vibration signal to obtain only the normal signal. Further, the measurement of the vibration signal may be a sum of all the signals obtained from the vibration sensor by frequency.

And, the setting value stored in the memory 140 is set based on the z-axis amplitude value obtained in a plurality of cleaning processes with normal cleaning results in accordance with using chemicals. For example, assuming that the average value of the amplitude at the rotation frequency obtained in the case of normal cleaning of about 1000 substrates using cleaning chemical of SC1 is 0.6, the lower limit is 0.5, and the upper limit is 0.7, any one of 0.5 to 0.575 can be set as the setting value with a margin of about 0 to 15% compared with the lower limit of 0.5. In other words, depending on the type of chemical used, the set value can be stored in the memory 140 with a margin at the lower limit of the z-axis amplitude value obtained in a number of cleaning processes with normal cleaning results, so that it is possible to know whether the contact state of the substrate and the cleaning brushes in the current cleaning process is normal compared with the set value recalled from the memory 140 during the substrate cleaning process.

On the other hand, if the z-axis amplitude measured value obtained during the cleaning process is less than the set value recalled from the memory 140, it is determined that the cleaning brushes 121, 122 are not in normal close contact with the substrate, and an alarm such as a warning signal or a warning window is output to inform the operator that the cleaning process needs to be corrected, or the cleaning process is stopped to prevent unnecessary continuation of the cleaning process.

Further, when the control unit 150 detects that the contact state of the cleaning brushes 121, 122 and the substrate W is poor, the contact state of the cleaning brushes 121, 122 and the substrate W may be corrected by the correction means by resetting the contact state of the cleaning brushes 121, 122. For example, the correction means may initialize the posture of the substrate W, or alternatively, change the posture of the substrate by moving the support apart from each other from holding position and then moving it back toward each other into the holding position.

That is, at least one of the two first supports 111 supporting the edges of the substrate W, and the two second supports 112, 112′ supporting the edges of the substrate W is movable 112d in a direction away from or toward each other.

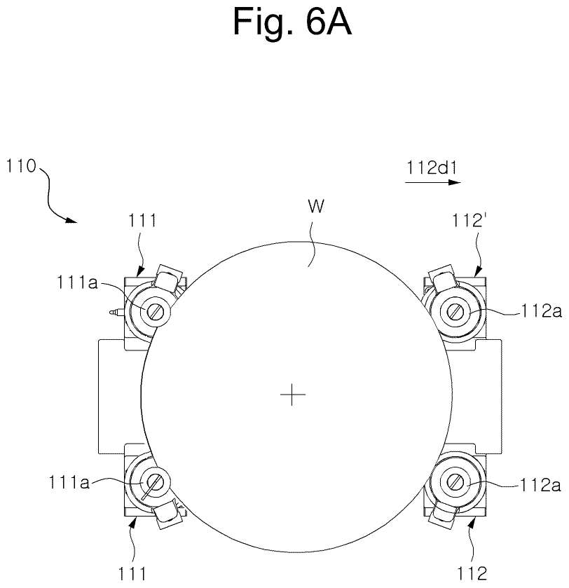

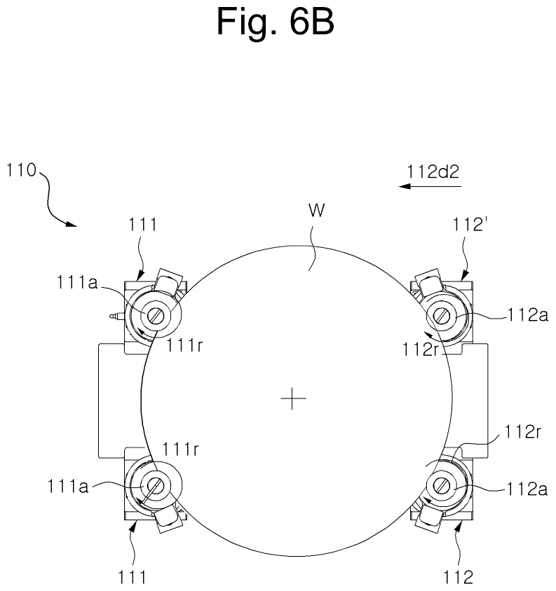

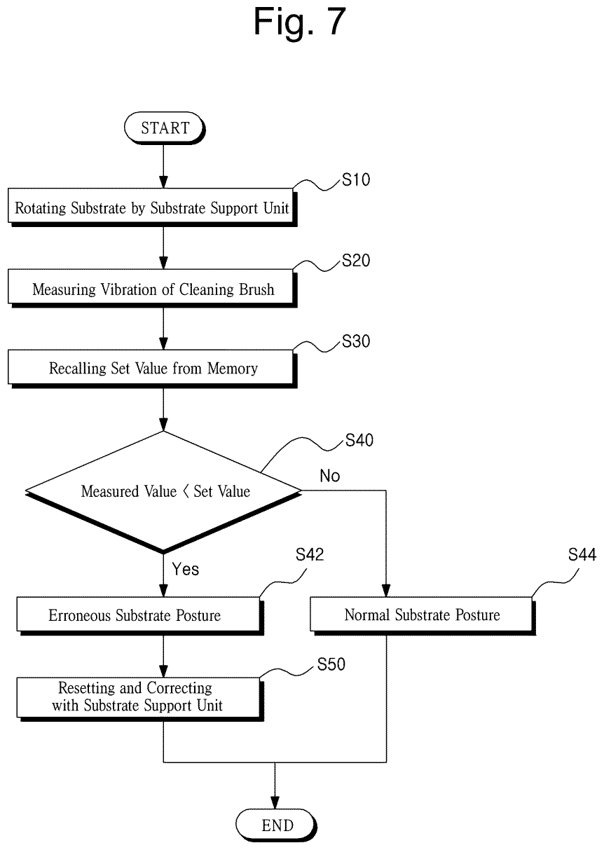

And, when the z-axis amplitude measurement obtained during the cleaning process is less than a set value recalled from the memory 140, the control unit 150 detects that a portion of the cleaning brushes is not in normal contact with the substrate W, and thus detects that the substrate is in poor posture. And, when the control unit 150 detects that the cleaning brushes 121, 122 are not in normal contact with the substrate, the control unit 150 resets the posture of the substrate or changes the posture of the substrate, as shown in FIG. 6A.

For example, the control unit 150 may retract 112d1 at least one of the first support 111 and the second support 112, 112′ to further increase the spacing between the first support 111 and the second support 112, 112′.

Here, the movement stroke in which at least one of the first support 111 and the second support 112, 112′ retracts in the direction of 112d1 is preferably sufficient to allow the edge of the substrate W to move from a pressed state to an unpressed state in the receiving recess 111x, 112x when the upper and lower cleaning brushes 121, 122 are in a non-contact state with the substrate W, and to prevent the edge of the substrate W from completely deviating from the receiving recess 111x, 112x. In contrast, when the substrate is located being pressed by the upper and lower cleaning brushes 121, 122, the movement stroke in which at least one of the first support body 111 and the second support body 112, 112′ is retracted in the direction of 112d1 may be defined as a length from a state in which the edge of the substrate W is pressed into the receiving recess 111x, 112x to a state in which the edge of the substrate W is completely disengaged from one of the receiving recess 111x, 112x.

Then, as shown in FIG. 6B, the control unit 150 advances in the direction of 112d2 at least one of the first support 111 and the second support 112, 112′ to narrow the distance between the first support 111 and the second support 112, 112′ so that an edge of the substrate W is pinched in the receiving recess 111x, 112x of the supports 111, 112, 112′.

As described above, when the edges of the substrate W are moved out of the receiving recess 111x, 112x of the supports 111, 112, 112′ and then reseated, the angle of inclination (ang) of the substrate is reset, so that the substrate W and the cleaning brushes 121, 122 are released from their previous state of poor contact, As the tilt angle (ang in FIG. 5) of the substrate W with respect to an imaginary horizontal plane As perpendicular to the direction of gravity is removed, whereby a new contact state of the substrate W and the cleaning brushes 121, 122 is established as a normal state corrected from the defective state.

On the other hand, the process of correcting the contact state of the substrate W and the cleaning brushes 121, 122 may be performed in multi-steps by a feedback control manner that gradually changes the degree of correction according to the vertical amplitude measurements measured by the vibration sensor after each step of correction.

For example, the control unit 150 moves at least one of the first support 111 and the second support 112, 112′ backward in the direction of 112d1 and then forward in the direction of 112d2 to narrow the distance between the first support 111 and the second support 112, 112′, thereby changing the state in which an edge of the substrate W is pinched in the receiving grooves 111x, 112x of the supports 111, 112, 112′. Then, the vertical amplitude in the z-axis direction is measured by the vibration sensor 130 while the cleaning brushes 121, 122 rotate in contact with the substrate W in the changed posture of the substrate W. If the measured amplitude in the z-axis direction falls short of the set value and is not within the acceptable range, but if the measured amplitude is closer to the set value than the previous measured value, the posture correction of the substrate W may be performed gradually in a feedback manner as multi-steps by causing the retraction stroke of the supports 111, 112 to be operated to a greater extent than previous retraction stroke of correction step and then advance again to the state which the substrate W is pinched in the receiving grooves 111x, 112x.

On the other hand, the vibration sensor 130 that detects the vibration of the cleaning brushes 121, 122 may be formed as a three-axis vibration sensor that, in addition to obtaining a vibration component in the z-axis direction perpendicular to the surface of the substrate, measures together the x-axis and y-axis vibration components, which are two horizontal directions perpendicular to the z-axis direction.

Accordingly, the control unit 150 receives a vibration component in the horizontal direction, which is the x-axis direction and the y-axis direction, among the measurements from the vibration sensor 130, and detects the size of foreign substances from the magnitude of the vibration component in the horizontal direction. In other words, in the case of a substrate that has been subjected to a chemical mechanical polishing process prior to the substrate cleaning process, large and small foreign objects remain on the surface of the substrate, and during the contact of the cleaning brushes 121, 122 with the substrate W, if the size of the foreign object is small, the vibration component in the horizontal direction appears small, and if the size of the foreign object is large, the vibration component in the horizontal direction appears large. Here, the conditions for measuring the vibration component in the horizontal direction vary depending on the chemical, so it can be determined the same as obtaining the z-axis vibration component described above.

Accordingly, when the foreign substances are detected as large, the control unit may increase the pressing force F1, F2 of the cleaning brushes 121, 122 and/or increase the rotation speed of the cleaning brushes 121, 122 so as to increase the removal efficiency of the defects remaining on the substrate W.

The above-disclosed subject matter is to be considered illustrative and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

In other words, while the foregoing embodiment exemplifies a configuration in which cleaning brushes are installed on both the upper and lower sides of the substrate W for contact cleaning, the present invention is not limited to this and includes a cleaning process in which cleaning brushes contact only one side of the substrate.

What is claimed is:

1. A substrate cleaning apparatus comprising:
a substrate support unit that rotates and holds the substrate;
a brush unit for cleaning the substrate with cleaning brushes formed in a roll and rotating in contact with the surface of the substrate;
a vibration sensor installed on the brush unit to detect vibrations generated by contact of the cleaning brush with the substrate;

2. The substrate cleaning apparatus of claim 1, further comprising:
a control unit for comparing a measured value by the vibration sensor with a set value stored in memory, and detecting an error in the contact state of the substrate and the cleaning brush if the measured value falls below the set value.

3. The substrate cleaning apparatus of claim 2, wherein the set value is obtained from experimental values obtained through a plurality of cleaning processes that result in the cleaning of the substrate by the cleaning brushes.

4. The substrate cleaning apparatus of claim 2, wherein the measured value and the set value are amplitude values at a rotational frequency of the cleaning brush.

5. The substrate cleaning apparatus of claim 2, wherein the measured value is obtained during a time period of at least one second of the cleaning time.

6. The substrate cleaning apparatus of claim 5, wherein the measured value is a sum of values measured during a time period of at least one second of the cleaning time.

7. The substrate cleaning apparatus of claim 5, wherein the measured value is a filtered value of a portion of the value measured for a time period of at least one second during the cleaning time.

8. The substrate cleaning apparatus of claim 2, wherein the vibration sensor measures a magnitude of the z-axis amplitude in the vertical direction as the measured value, and the control unit detects a posture error of the cleaning brush and the substrate from the magnitude of the z-axis amplitude in the vertical direction

9. The substrate cleaning apparatus of claim 2, wherein the vibration sensor is a three-axis vibration sensor that measures a magnitude of the x-axis and y-axis amplitude in the horizontal direction as well as a magnitude of the z-axis amplitude in the vertical direction.

10. The substrate cleaning apparatus of claim 9, wherein the control unit detects the size of foreign substances on the substrate from the magnitude of the x-axis and y-axis amplitude in the horizontal direction.

11. The substrate cleaning apparatus of claim 1, wherein the vibration sensor is an acceleration sensor.

12. The substrate cleaning apparatus of claim 2, wherein the control unit outputs an alarm when a contact state of the substrate and the cleaning brush is detected as error based on the measured value falling below the set value.

13. The substrate cleaning apparatus of claim 2, wherein the control unit stops cleaning of the substrate by the cleaning brushes when a contact state of the substrate with the cleaning brushes is detected as erroneous based on that the measured value falls below the set value.

14. The substrate cleaning apparatus of claim 2, wherein the substrate support unit includes:
at least two first supports of supporting an edge of the substrate, and;
at least one second support of supporting an edge of the substrate and of being movable in a horizontal direction with respect to the first supports;
wherein the substrate is supported in a horizontal state by the first supports and the second support and is rotated by a rotation of the first support.

15. The substrate cleaning apparatus of claim 14, wherein the control unit varies the posture of the substrate by retracting and advancing at least one of the first support and the second support, when the measured value falls below the set value and the contact state of the substrate with the cleaning brush is detected as erroneous.

16. The substrate cleaning apparatus of claim 1, wherein, when the measured value by the vibration sensor in vertical direction falls below the set value, the control unit detects that the substrate has a poor posture in that a portion of the cleaning brush is not in contact with the substrate.

17. A substrate cleaning apparatus, comprising:
a substrate support unit that rotates and supports the substrate;
a brush unit for cleaning the substrate with cleaning brushes formed in a roll and rotating in contact with the surface of the substrate;
a vibration sensor installed on the brush unit to detect vibrations in the vertical direction generated by the contact of the cleaning brush with the substrate;
a correction means for correcting the posture of the substrate when an magnitude of the vibration amplitude measured by the vibration sensor falls below a predetermined value.

18. The substrate cleaning apparatus of claim 17, wherein the correction means initializes the posture of the substrate.

19. The substrate cleaning apparatus of claim 17, wherein the correction means changes the posture of the substrate by moving backward and then forward at least portion of supports of supporting the substrate.

20. The substrate cleaning apparatus of claim 17, wherein the correction means corrects the posture of the substrate in a feedback manner that gradually changes the degree of correction according to the amplitude measured by the vibration sensor after each correction.
